(19) United States
(12) Patent Application Publication
(10) Pub. No.: US 2014/0224308 A1
(43) Pub. Date: Aug. 14, 2014

(54) NANOPARTICLES FOR A SOLAR POWER SYSTEM AS WELL AS A SOLAR CELL WITH SUCH NANOPARTICLES

(71) Applicant: Martin Buskuhl, Berlin (DE)

(72) Inventor: Martin Buskuhl, Berlin (DE)

(21) Appl. No.: 14/130,049

(22) PCT Filed: Jun. 28, 2012
(86) PCT No.: PCT/IB2012/001800

§ 371 Date: Apr. 10, 2014

(30) Foreign Application Priority Data
Jun. 30, 2011 (DE) 202011103301.9

(51) Int. Cl. H01L 31/0352

(52) U.S. Cl. CPC H01L 31/035218
USPC 136/255

(57) ABSTRACT

Nanoparticle for a solar power system for increasing light utilisation, with a core selected from materials comprising metals, metal alloys, semi-conductors, electrically conductive non-metals, electrically conductive compounds and mixtures thereof, whereby at least one first shell is arranged around the core.

The present invention relates to nanoparticles for a solar power system for increasing light utilisation, with a core selected from materials comprising metals, metal alloys, semi-conductors, electrically conducting non-metals, electrically conducting compounds and mixtures thereof, as well as a solar cell with at least one such nanoparticle.

Known from WO 2009/043340 is a photovoltaic module with at least one solar cell, in which the nanoparticles for light amplification are incorporated. These nanoparticles can be of a particular geometry and arrangement in order to amplify incident light.

However, it has been show that the geometry and arrangement of nanoparticles in a photovoltaic module alone do not lead to optimum results.

The aim of the present invention is therefore to further develop nanoparticles for a solar power system of the type set out in the introduction, in such a way the in a solar power plant or solar cell they result in better light amplification than in the prior art.

This is achieved in accordance with the invention in that at least one first shell is arranged around the core.

Applying the core/shell principle to nanoparticles for a solar power system gives a person skilled in the art a large number of possibilities of physically and chemically manipulating nanoparticle in such a way that depending in use optimal amplification of light can be achieved.

A further advantage of the present invention is that arranged around the core is at least one second shell, at a larger distance from the core than the at least one first shell.

By providing a second shell, further combinations of physical and chemical properties of a nanoparticle can created. What is meant by the present invention is that a first shell always surrounds a core and then any sequence of first and second shells is arranged.

Another advantage of the present invention is that a first connection layer is arranged between the core and the first shell. The first connection layer ensures that good adhesion between the core and the first shaft is produced.

It is also of advantage that a second connection layer is arranged between the first shell and the second shell. The second connection layer ensures that good adhesion is achieved between the first shell and the second shell.

Further advantages of the present invention in relation to the nanoparticles are set out in the features of the sub-claims.

Another advantage of the present invention in relation to a solar cell is that a plurality of nanoparticles is arranged in a semiconductor layer. This ensures that the nanoparticles do not only have to be present in a scattered manner in the semiconductor layer, but in certain forms of embodiment are also packed so densely that they form the semiconductor layer if one of the first or second shells is a semiconductor layer. In some forms of embodiment it is also advantageous if the gaps between the nanoparticles are filled with semiconductor material. In other forms of embodiment it is advantageous if the gaps between the nanoparticles are filled with other materials, e.g. dielectric material or conductive material.

Such dense packing is advantageous in that the majority of nanoparticles are arranged in such a way that at least some of the nanoparticles are in contact with each other or with the first or second shell and the contacting shells of the nanoparticles form the semiconductor layer.

Forms of embodiment of the present invention are described below in more detail with the aid of the drawings. In these:

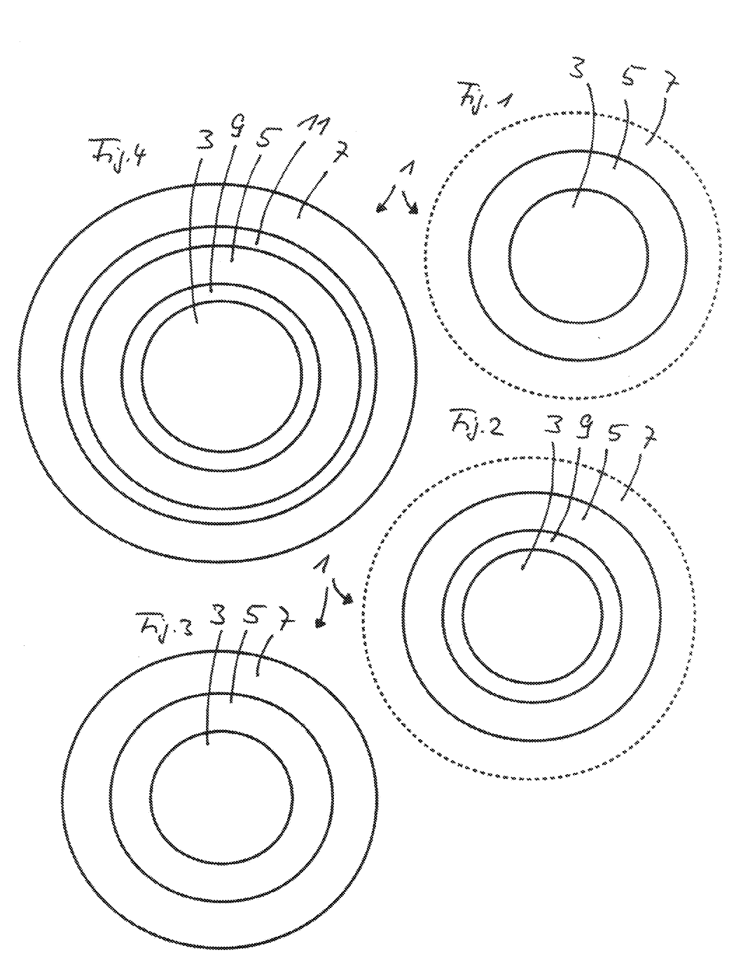

FIG. 1 shows a schematic round nanoparticle with a core and a first and second shell in accordance with a first form of embodiment of the present invention;

FIG. 2 shows a schematic nanoparticle with a core, a first connection layer, a first shell and a second shall in accordance with a second embodiment of the present invention;

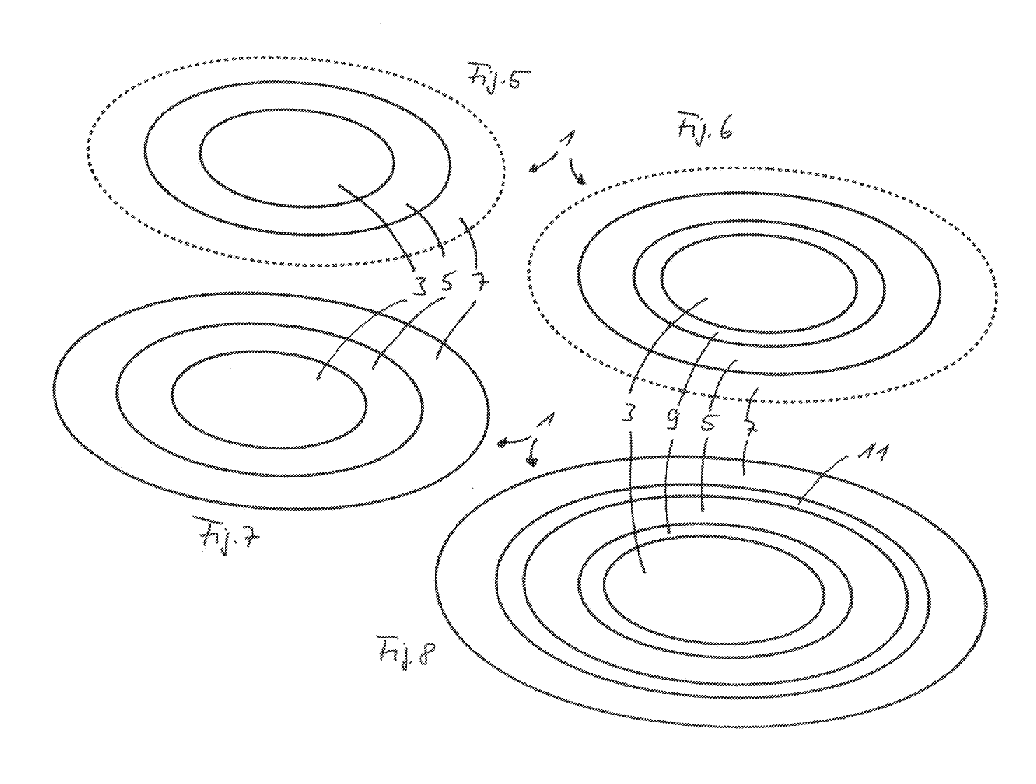

FIG. 3 shows a schematic nanoparticle with a core and a first and second shell in accordance with a third form of embodiment of the present invention;

FIG. 4 shows a schematic nanoparticle with a core, a first connection layer, a first shell, a second connection layer and a second shell in accordance with a fourth embodiment of the present invention;

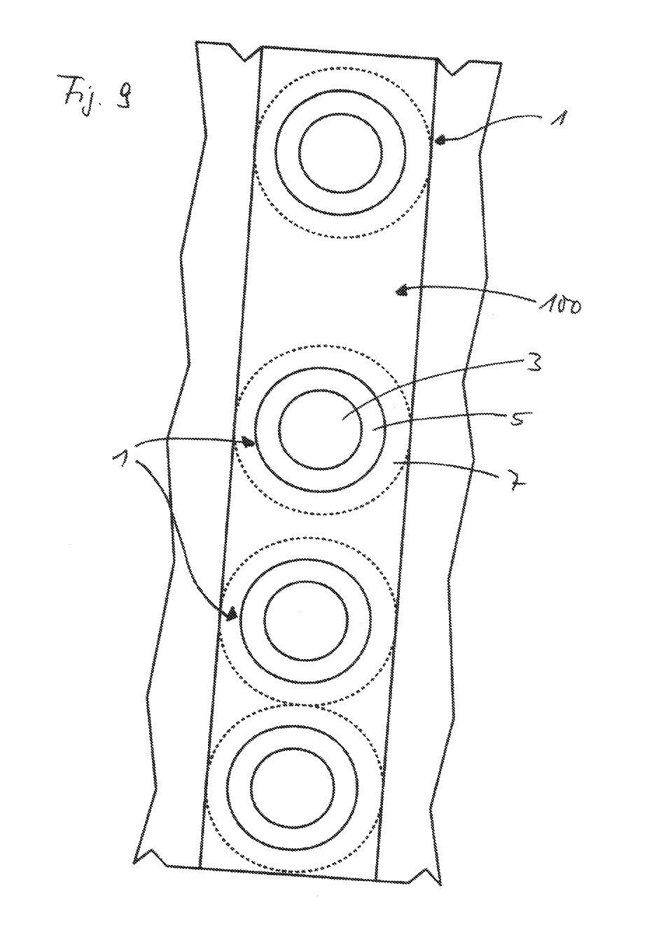

FIG. 5 shows a nanoparticle as in FIG. 1, but in an ellipsoid form;

FIG. 6 shows a nanoparticle as in FIG. 2, but in an ellipsoid form;

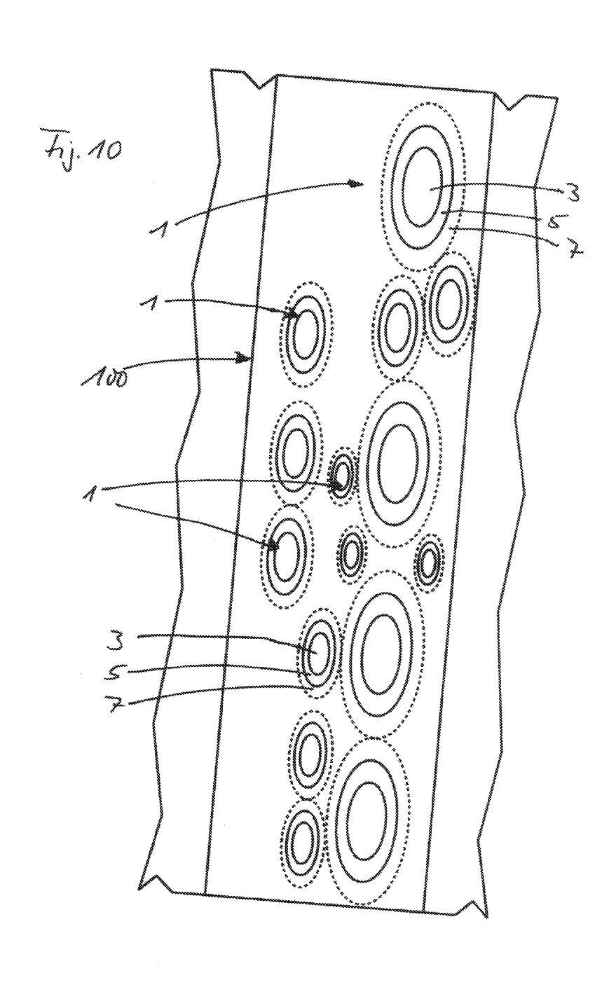

FIG. 7 shows a nanoparticle as in FIG. 3, but in an ellipsoid form;

FIG. 8 shows a nanoparticle as in FIG. 4, but in an ellipsoid form;

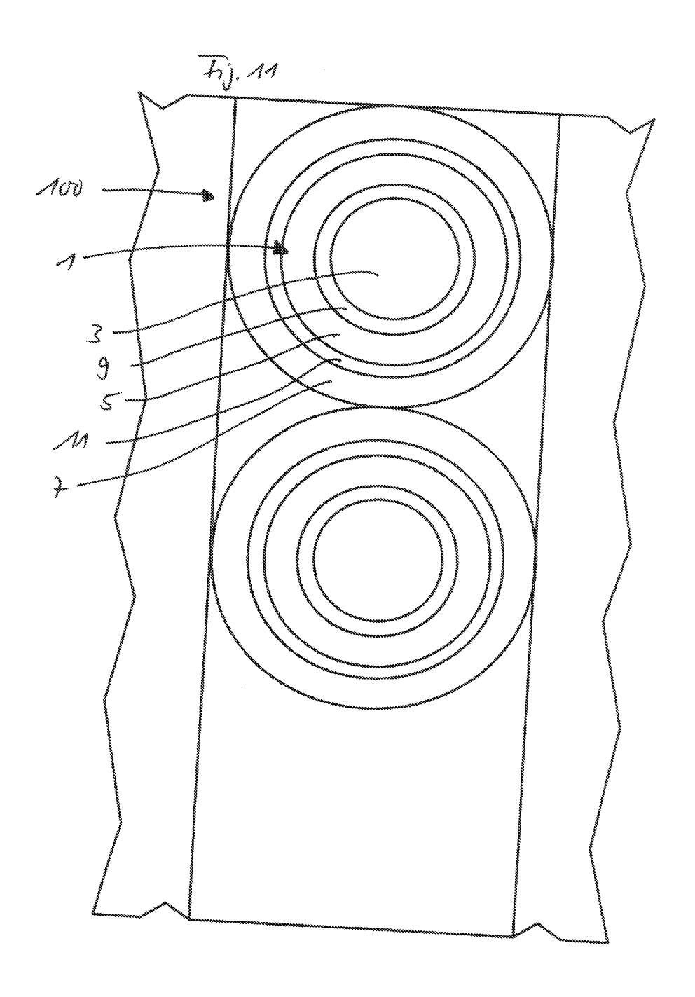

FIG. 9 shows a schematic partial view of a solar cell with nanoparticles in accordance with FIG. 1;

FIG. 10 shows a schematic solar cell with nanoparticles in accordance with FIG. 5 but in a different size; and

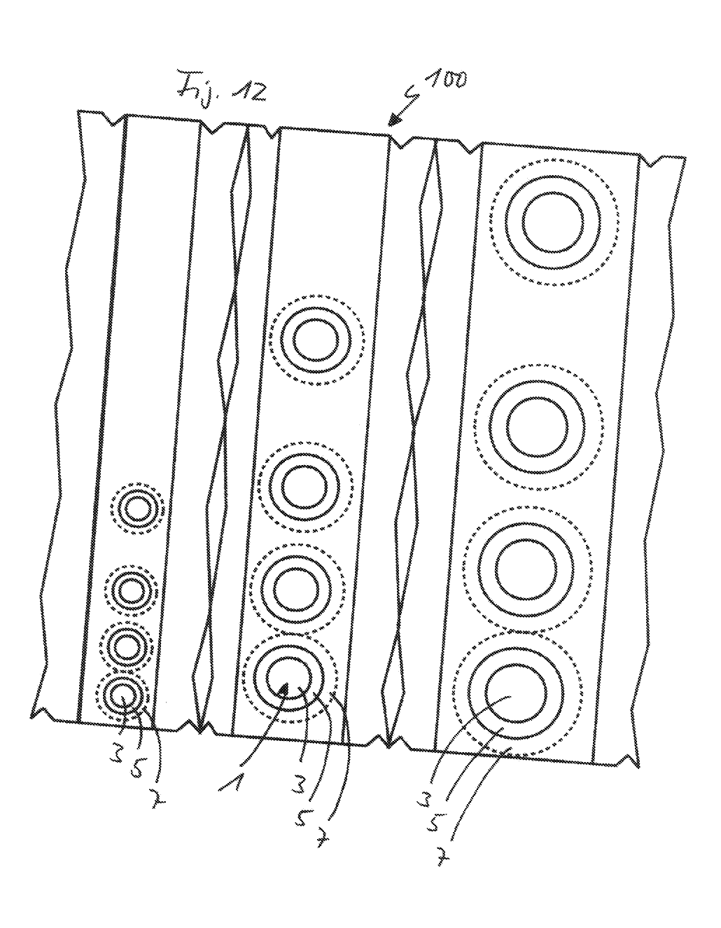

FIG. 11 shows schematic solar cell with nanoparticles in accordance with FIG. 4.

FIG. 12 shows a schematic solar cell with nanoparticles in accordance with FIG. 1, sorted by size.

FIG. 1 shows a schematic nanoparticle 1 having a core 3, a first shell 5 surrounding the core 3 and a second shell 7 surrounding the first shell 5. In this first form of embodiment the first shell 5 directly adjoins the core 3 and the second shell 7 directly adjoins the first shell 5.

FIG. 2 basically shows the same nanoparticle 1 but in a second form of embodiment having a first connection layer 9 between the core 3 and the first shell 5.

In a third form of embodiment in FIG. 3 a nanoparticle 1 is shown which in terms of its structure is identical to the nanoparticle 1 in FIG. 1. The only difference is the property of the second shell 7. The first shell in FIG. 3 is usually a dielectric material. The second shell 7 in FIG. 3 is usually made of another material, for example a photo-active semiconductor, such as CIGS or Si for example.

In FIG. 4 a fourth form of embodiment of a nanoparticle 1 is shown. In this fourth form of embodiment there is also a second connection layer 11 between the first shell 5 and the second shell 7. The nanoparticle in FIG. 4 therefore has a core 3, a first connection layer 9, second shell 5, a second connection layer 11 and a second shell 7. The first shell in FIG. 4 is usually a dielectric material. The second shell 7 in FIG. 4 is usually made of another material, for example a photo-active semiconductor such as CIGS or Si.

FIG. 5 shows a nanoparticle 1 in a variant of the first form of embodiment. In this variant the nanoparticle 1 is ellipsoid.

FIG. 6 shows a variant of the second form of embodiment in FIG. 2. The nanoparticle 1 in FIG. 6 is also ellipsoid. The nanoparticle 1 in FIG. 7 is an ellipsoid variant of the third form of embodiment of the nanoparticle 1 in FIG. 3. The nanoparticle 1 in FIG. 8 is also an ellipsoid variant of the nanoparticle 1 in FIG. 4.

In all forms of embodiment the core 3 is made optionally of metals, transition metals, semi-metals, conductive or semi-conductive non-metal compounds, or mixtures, alloys and compounds of said materials. The production of cores is not the subject matter of the present invention. A person skilled in the art can produce cores 3 for the relevant application as he chooses. The shape and size of the cores 3 of the nanoparticle 1 in accordance the present invention are either spherical or ellipsoid, cylinder or rod-shaped with and without rounded ends, conical or pyramidal, cubic or block-shape, irregular or variable in size in the micro-, nano- or subnanometre range.

For use in solar power systems, in accordance with the present invention at least one first shell 5 should be added to the core. The at least one shell 5 should have certain chemical or physical properties which in conjunction with the core 3 ensure amplification of light in a solar power system.

Although in the figures two shells are always shown, in accordance with the present invention at least a first shell 5 should be present. The provision of a second shell 7 is optional and serves to optimise the properties of the nanoparticle 1 in the application in question. The shape and size of the first shell 5 or the second shell 7 is preferably such that the first shell 5 adjoining the core 3 fairly evenly surrounds it. However, other shapes are conceivable in other forms of embodiment, e.g. a pyramidal core in spherical shell. The thickness of the first shell 5 and the second shell 7 can vary from one atom layer to the micrometre range.

The first shell 5 and/or the second shell 7 can be identical or different and connected directly to each other or with the core 3 or via the first connection layer 9 or the second connection layer 11. The first and/or second shell 5, 7 is thus made of either non-conductive materials, such as, for example, halogenides, preferably fluorides, such as, for example CaF2 or MgF2,chalkigenides, preferably, for example, oxides etc. The first shell 5 and/or the second shell 7 can also consist of semi-conductive materials, conductive materials (for example TCO variants, light-permeable materials, light-absorbing and/or light-transforming materials, for example CIGS, CdTe, Si, organic semi-conductors etc.) as well as inorganic or organic materials. Finally, the first shell 5 and/or the second shell 7 can also exhibit special chemical and/or physical properties which ensure that the nanoparticles 1 become arranged in a predetermined manner (with regard to each other or to the surface in a local environment). This can result in a dense or loosened monolayer or in a compact nanoparticle layer made up of a pure type of a mixture of types. Various interactions can be responsible for producing the arrangement of nanoparticles, for example chemical or physical interactions, for instance van der Waals, adhesion, ion forces, or electrostatic or electromagnetic interactions.

In the second and fourth form of embodiment according to FIG. 2 and FIG. 4 the first connection layer 9 is provided between the core 3 and the first shell 5, and the second connection layer 11 between the first shell 5 and the second shell 7. Such first and second connection layers 9, 11 preferably consist of organic or inorganic materials, which intercede between the chemical and physical properties of shell and core (first connection layer 9) or between two adjacent shells (second connection layer 11).

Such organic materials can be organic compounds which bear various functional groups in order to allow adhesion on both sides (core/shell, first shell/second shell etc.). The first and second connection layers 9, 11 are preferably as thin as possible.

In all the figures the outermost shell of a nanoparticle 1 is the second shell 7 and in FIG. 1, FIG. 2, FIG. 5 and FIG. 6 this is shown schematically with a broken line. In other forms of embodiment the first shell 5 can also be the outer shell. This depends entirely on the selected alternating sequence.

FIG. 9 schematically shows part of a solar cell 100 in which several nanoparticles 1 are arranged in accordance with the form of embodiment shown in FIG. 1.

FIG. 10 schematically shows part of a solar cell in a variant in which the nanoparticles 1 shown in FIG. 5 are of a different size.

FIG. 11 schematically shows part of a solar cell 100 in which the nanoparticles 1 are arranged in accordance with the fourth form of embodiment (FIG. 4).

FIG. 12 schematically shows part of a solar cell 100 in which the nanoparticles 1 in accordance with a first form of embodiment (FIG. 1) are arranged sorted by size. In this way different frequency ranges of the incident light can be optimally converted or intensified at the relevant penetration depths. For example, short-wave light can optimally interact close to the surface with possibly smaller nanoparticles 1, and long-wave light, penetrating more deeply can optimally interact with possibly larger nanoparticles 1. In FIG. 12 the light enters from the left side. FIG. 12 can on the one hand represent a single solar cell, the active semi-conductor of which comprises several layers of nanoparticles 1, or it can represent a multi-junction cell arranged in a stacked manner. For the present invention the frequency range of the “light” acting on a solar cell 100 are not critical. The present invention can be used in combination with all type of electromagnetic radiation, e.g. also infrared/hear radiation (e.g. thermo-photovoltaic), microwaves etc.

During the manufacturing of solar cell 100 in any variant, nanoparticles 1 are applied, for example though spin coating, dipping, self-assembling, wet-chemical deposition, sol-gel-method, segregation/aggregation, physical methods (e.g. distribution through electromagnetic properties or electrostatic properties and potentials, gaseous phase separation, printing techniques, e.g. similar to inkjet printing, direct contact transmission, spray method. Nanoparticles can be produced and deposited completely or in parts on the surface or in the vicinity. This normally takes place with wet chemical methods or physical manufacturing processes (e.g. gaseous phase separation, plasma methods etc.).

Finally it is also possible for the nanoparticles 1 to be applied between separately applied layers of the “embedding” material. The layers are then “at the top” and “at the bottom” and may have to be doped. Envisaged as embedding material for nanoparticles 1 are, depending on the application purpose, dielectric materials, semi-conductors, TCO, where doping may be required. The embedding material can also fill out the spaces between the nanoparticles

The purpose of the outer shell is simply to organise the distribution and/or adhesion of the nanoparticles 1 in the local environment, and it may be possible and/or sensible to chemically or physically remove the parts of this shell that are no longer required. Outer shells can be melted through carrying out a targeted reaction. Through such a melting process the embedding, particularly of the cores in a relatively homogeneous or uniform environment is improved. If the outer shell consists of a photoactive semi-conductor, melting of these shells can lead at least to larger contact surface and possibly the formation of a complete semi-conductor layer. Thus, through the reduction in interfaces and the longer possible paths, the conductivity for produced electron-hole pairs is considerably improved.

Optimisation parameters for the first shell 5 and/or the second shell 7 are given, for example, from the individual properties of the core 3 and the first shell 5 and/or second shell 7 resulting in the sum of macroscopic properties looking completely different from the core 3, the first shell 5 or the second shell 7 alone. One optical property is, for example, that the first shell 5 or the second shell 7 has a higher refractory index than the surrounding layers. With oblique incident light, the light migrates through the shell and interacts several times with the nanoparticles 1.

Finally, changes to the shape and size can preferably amplify different frequency ranges.

In other forms of embodiment, in addition to the dielectric shell, the nanoparticles 1 also have a conductive shell which produces a conductive contact between the layers and allows the conducing of the charge carriers. This is of particular interest if the nanoparticles 1 are surrounded with a photoactive semi-conductor layer in which the charge carriers are produced. To assure the technical function these must be quickly separated and conducted away so that they do no recombine. This could take place though a TCO layer being inserted under the semi-conductor layer and the charge carriers being removed via the inner side of the nanoparticles 1. Alternatively or in addition the TCO layers can be applied to the outside around the semi-conductor. In this case the charges can also be removed around the outside. It is important that the doping, the conductivities and pn-transition are correctly set. Such setting is familiar to a person skilled in the art and is not part of the invention.

In forms of embodiment in which the TCO layer lies below the semi-conductor, additional electrical contacts can be created in order to conduct the electrons from the TCO layer to the outside.

If the outermost shell of a nanoparticle 1 is not required for the operation of a solar cell, e.g. it only serves to arrange the nanoparticles by means of an adhesive effect, this shell can be removed after arranging the nanoparticles 1.

### LIST OF REFERENCE

1 nanoparticles
3 core
5 first shell
7 second shell
9 first connection layer
10 second connection layer
100 solar cell

1. Nanoparticle for a solar power system for increasing light utilisation, with a core selected from material comprising metals, metal alloys, semiconductors, electrically conducting non-metals, electrically conduction compounds and mixtures thereof,
characterised in that
at least one first shell (5) is arranged around the core (3).

2. Nanoparticle according to claim 1,
characterised in that
arranged around the core (3) there is at least one second shell (7) at a greater distance from the core (3) than the at least one first (5).

3. Nanoparticle according to claim 1,
characterised in that
a first connection layer (9) is arranged between the core (3) and the first shell (5).

4. Nanoparticle according to claim 2,
characterised in that
a second connection layer (11) is arranged between the first shell (5) and the second shell (7).

5. Nanoparticle according to claim 1,
characterised in that
the at least one first shell (5) is a dielectric shell.

6. Nanoparticle according to claim 2,
characterised in that
the at least one second shell (7) is a dielectric shell.

7. Nanoparticle according to claim 2,
characterised in that
the at least one second shell (7) is a conductive shell.

8. Nanoparticle according to claim 2,
characterised in that
the at least one second shell (7) is a semi-conductive shell.

9. Nanoparticle according to claim 8,
characterised in that
the at least one second shell (7) is an active semi-conductor, such as CIGS for example.

10. Nanoparticle according to claim 2,
characterised in that
the at least one second shell (7) has an adhesive effect in order to adhere to its surroundings.

11. Solar cell with at least one nanoparticle according to claim 1.

12. Solar cell according to claim 11,
characterised in that
a plurality of nanoparticles (1) is arranged in the semi-conductor layer.

13. Solar cell according to claim 12,
characterised in that
the plurality of nanoparticles (1) is arranged in such a way that at least some of the nanoparticles (1) are in contact with each other with the first or second shell (5; 7).

14. Solar cell according to claim 13,
characterised in that
the contacting first or second shells (5; 7) of the nanoparticles (1) form the semi-conductor layers.
